(19) United States
(12) Patent Application Publication
(10) Pub. No.: US 2019/0296154 A1
(43) Pub. Date: Sep. 26, 2019

(54) ARRAY SUBSTRATE AND METHOD FOR MANUFACTURING SAME

(71) Applicant: Wuhan China Star Optoelectronics Technology Co., Ltd., Wuhan Hubei (CN)

(72) Inventor: Yuebai HAN, Wuhan Hubei (CN)

(21) Appl. No.: 16/072,504

(22) PCT Filed: Apr. 12, 2018
(86) PCT No.: PCT/CN2018/082734

§ 371 Date: Jul. 25, 2018

(30) Foreign Application Priority Data
Mar. 19, 2018 (CN) 201810223632.2

(51) Int. Cl. H01L 29/786; H01L 29/66

(52) U.S. Cl. CPC H01L 29/78633; H01L 27/1262; H01L 29/66757; H01L 29/78675

(57) ABSTRACT

The present disclosure provides an array substrate and a method for manufacturing the same. The array substrate includes a base plate; a metal light-shielding layer disposed on a surface of the base plate; and a polysilicon layer disposed on the metal light-shielding layer. An area of the metal light-shielding layer is greater than or equal to an area of the polysilicon layer, and a projection of the polysilicon layer on the metal light-shielding layer falls within a region constricted by the metal light-shielding layer. A thickness of the polysilicon layer is uniform.

### FIELD OF INVENTION

The present disclosure relates to the field of manufacturing array substrate, and more particularly to an array substrate and a method for manufacturing the same.

### BACKGROUND

Low-temperature polysilicon display panels possess advantages including having a high resolution, high mobility, and low power consumption, and thus low-temperature polysilicon display panels have become essential products of flat panel displays and are widely used in mobile phones and tablet computers for those brands such as APPLE, SAMSUNG, HUAWEI, XIAOMI, AND MEIZU. Because manufacturing low-temperature polysilicon devices is complicated, a top-gate structure is used. For this reason, a metal light-shielding (LS) layer is first formed on a surface of the glass. That is, with regard to structure of a low-temperature polysilicon display panel, the metal light-shielding layer is the layer first formed on the base plate, and the metal light-shielding layer is disposed below all the layers constituting array of devices. Conventionally, a polysilicon layer is formed to cross edges of metal light-shielding layer. However, this makes the polysilicon layer at edges of metal light-shielding layer excessively thin and even possibly discontinuous. Abnormal electrical property occurs in an inclined slope portion of the polysilicon layer at edges of metal light-shielding layer, and bright or dark spot defects are generated.

Therefore, to solve the problems encountered by the prior art, there is a need to provide an array substrate and a method for manufacturing the same.

### SUMMARY OF DISCLOSURE

The present disclosure provides an array substrate and a method for manufacturing the same. According to the present disclosure, the polysilicon layer does not cross edges of the metal light-shielding layer, avoiding the problem that the polysilicon layer at edges of metal light-shielding layer is excessively thin. Moreover, electrical property of the polysilicon layer is improved, and product yield is increased.

To solve the above-said problems, the present disclosure provides the following technical schemes.

In a first aspect, the present disclosure provides an array substrate, comprising:

a base plate;

a metal light-shielding layer disposed on a surface of the base plate; and

a polysilicon layer disposed on the metal light-shielding layer;

wherein an area of the metal light-shielding layer is greater than or equal to an area of the polysilicon layer, and a projection of the polysilicon layer on the metal light-shielding layer falls within a region constricted by the metal light-shielding layer; and

wherein edges of the metal light-shielding layer are straight, bent, or curved.

In accordance with one preferred embodiment of the present disclosure, the metal light-shielding layer is U-shaped.

In accordance with one preferred embodiment of the present disclosure, a width of the metal light-shielding layer is greater than a width of the polysilicon layer by 0.5-2 micrometers.

In accordance with one preferred embodiment of the present disclosure, the metal light-shielding layer is rectangle-shaped, or trapezoid-shaped.

In a second aspect, the present disclosure provides a method for manufacturing an array substrate, comprising:

a step S1 of providing a base plate and forming a metal light-shielding layer on the base plate, the metal light-shielding layer including a plurality of portions spaced from each other;

a step S2 of forming a first buffer layer having a thickness identical to a thickness of the metal light-shielding layer on the base plate, and patterning the first buffer layer to remove a portion of the first buffer layer corresponding to and disposed above the metal light-shielding layer, such that the patterned first buffer layer is coplanar with the metal light-shielding layer;

a step S3 of forming a second buffer layer having a predetermined thickness on the patterned first buffer layer and the metal light-shielding layer; and

a step S4 of forming a polysilicon layer on the second buffer layer to correspond to the metal light-shielding layer, wherein a thickness of the polysilicon layer is uniform.

In accordance with one preferred embodiment of the present disclosure, the metal light-shielding layer is U-shaped, rectangle-shaped, or trapezoid-shaped.

In accordance with one preferred embodiment of the present disclosure, edges of the metal light-shielding layer are straight, bent, or curved.

In accordance with one preferred embodiment of the present disclosure, a projection of the polysilicon layer on the base plate falls within a region constricted by a projection of the metal light-shielding layer on the base plate.

In accordance with one preferred embodiment of the present disclosure, a projection of the polysilicon layer on the base plate does not entirely overlap a projection of the metal light-shielding layer on the base plate.

In a third aspect, the present disclosure provides an array substrate, comprising:

a base plate;

a metal light-shielding layer disposed on a surface of the base plate; and

a polysilicon layer disposed on the metal light-shielding layer;

wherein an area of the metal light-shielding layer is greater than or equal to an area of the polysilicon layer, and a projection of the polysilicon layer on the metal light-shielding layer falls within a region constricted by the metal light-shielding layer.

In accordance with one preferred embodiment of the present disclosure, the metal light-shielding layer is U-shaped.

In accordance with one preferred embodiment of the present disclosure, a width of the metal light-shielding layer is greater than a width of the polysilicon layer by 0.5-2 micrometers.

In accordance with one preferred embodiment of the present disclosure, the metal light-shielding layer is rectangle-shaped, or trapezoid-shaped.

Compared to the prior art, the present disclosure is characterized in that the metal light-shielding layer is formed on the base plate to have a U-shape, a rectangle-shape, or a trapezoid-shape and to have a size larger than the polysilicon layer (just 1 micrometer wider required), so that the metal light-shielding layer completely covers the polysilicon layer. This ensures that the polysilicon layer does not cross edges of the metal light-shielding layer, avoiding the problem that the polysilicon layer at edges of metal light-shielding layer is excessively thin. Alternatively, the buffer layer is formed by formation of a first buffer layer and a second buffer layer. The first buffer layer is formed first to have a thickness identical to a thickness of the metal light-shielding layer, and then the first buffer layer is patterned such that the patterned first buffer layer is coplanar with the metal light-shielding layer. Thereafter, the second buffer layer is formed on the patterned first buffer layer and the metal light-shielding layer. Since the buffer layer has a planar top surface on which the polysilicon layer is formed later, a thickness of the polysilicon layer is uniform. Thus, electrical property of the polysilicon layer is improved, and product yield is increased.

### BRIEF DESCRIPTION OF DRAWINGS

To explain in detail the technical schemes of the embodiments or existing techniques, drawings that are used to illustrate the embodiments or existing techniques are provided. The illustrated embodiments are just a part of those of the present disclosure. It is easy for any person having ordinary skill in the art to obtain other drawings without labor for inventiveness.

FIG. 1 shows a top view of a partial structure of an array substrate of the prior art.

FIG. 2 shows a cross-sectional view of a partial structure of an array substrate of the prior art.

FIG. 3 shows a top view of a partial structure of an array substrate according to the present disclosure.

FIG. 4 shows a cross-sectional view of the array substrate of FIG. 3 along line A-A according to the present disclosure.

FIG. 5 shows a cross-sectional view of the array substrate of FIG. 3 along line B-B according to the present disclosure.

FIG. 6 is a schematic diagram showing a cross-sectional view of a partial structure of an array substrate according to the present disclosure.

FIG. 7 shows a flowchart of a method for manufacturing an array substrate according to the present disclosure.

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, the same reference symbol represents the same or similar components.

The subject invention solves the problems existing in conventional polysilicon thin film transistors, where the polysilicon layer crosses edges of the metal light-shielding layer, which makes the polysilicon layer at edges of the metal light-shielding layer excessively thin and even possibly discontinuous, and further leads to occurrence of abnormal electrical property in inclined slope portion of the polysilicon layer at edges of the metal light-shielding layer, and generation of bright or dark spot defects.

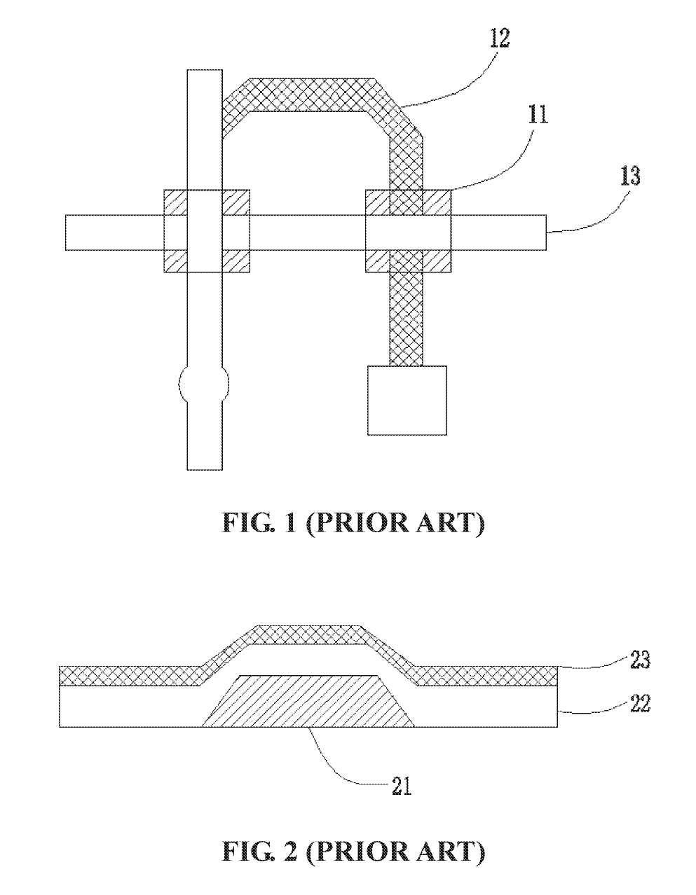

Please refer to FIG. 1, which shows a top view of a partial structure of an array substrate of the prior art. The conventional array substrate includes a metal light-shielding layer 11 including a plurality of rectangular portions spaced from each other; a polysilicon layer 12 disposed on the metal light-shielding layer 11; and a gate electrode disposed insulatively on the polysilicon layer 12. A projection of the polysilicon layer 12 on the metal light-shielding layer 11 crosses edges of the metal light-shielding layer 11.

Specifically, please refer to FIG. 2, which shows a cross-sectional view of a partial structure of an array substrate of the prior art. A buffer layer 22 is sandwiched between the metal light-shielding layer 21 and the polysilicon layer 23. Since formation of the metal light-shielding layer 21 creates a protrusion at corresponding region of the substrate, the buffer layer 22 formed thereafter also creates a protrusion at corresponding region of the substrate. Therefore, as the polysilicon layer 23 is formed later, the polysilicon layer 23 crosses edges of the metal light-shielding layer 21. An inclined slope portion is generated in the polysilicon layer 23 at edges of the metal light-shielding layer 21. (That is, top surfaces of the films formed at this location are not planar but have a tilt angle.) This makes the polysilicon layer at edges of the metal light-shielding layer excessively thin and even possibly discontinuous, and further leads to occurrence of abnormal electrical property of the polysilicon layer 23, and generation of poor display quality such as bright or dark spot defects.

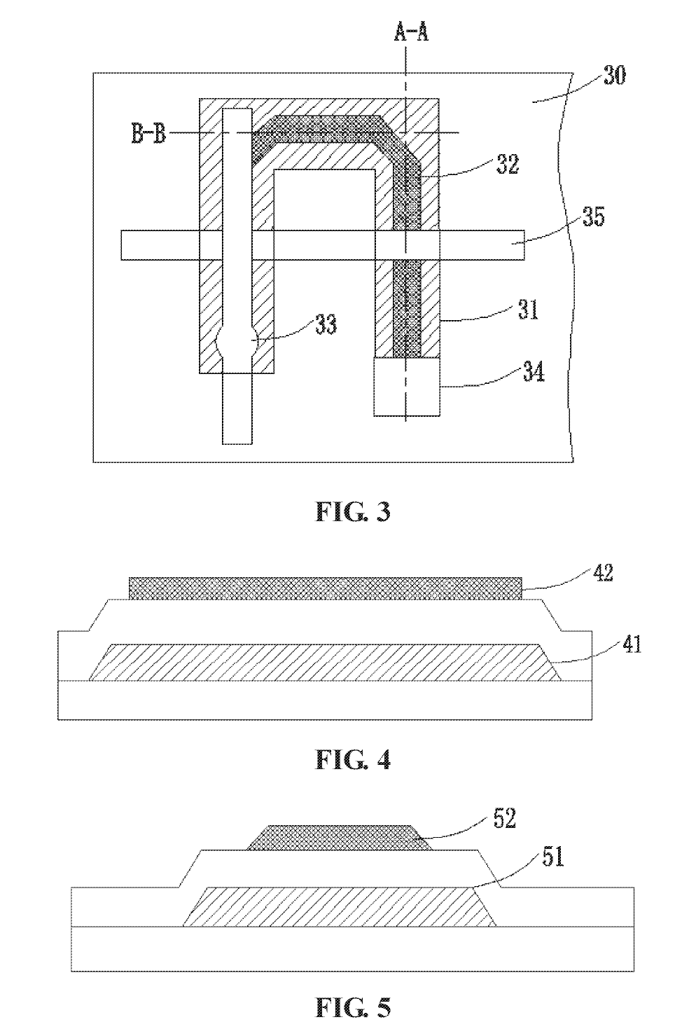

Please refer to FIG. 3, which shows a top view of a partial structure of an array substrate according to the present disclosure. The array substrate provided by the present disclosure includes: a base plate 30; a metal light-shielding layer 31; a polysilicon layer 32 disposed on the metal light-shielding layer 31; a source electrode 33 disposed at a source region of the polysilicon layer 32; a drain electrode 34 disposed at a drain region of the polysilicon layer 32; and a gate electrode 35 disposed insulatively on the polysilicon layer 32. An area of the metal light-shielding layer 31 is greater than or equal to an area of the polysilicon layer 32. The metal light-shielding layer 31 is formed to correspond to pattern of the polysilicon layer 32. The polysilicon layer 32, the source electrode 33, and the drain electrode 34 constitutes a U-shape. Preferably, the metal light-shielding layer 31 is U-shaped, and a projection of the polysilicon layer 32 on the metal light-shielding layer 31 falls within a region constricted by the metal light-shielding layer 31. A width of the metal light-shielding layer 31 is greater than a width of the polysilicon layer 32 by 0.5-2 micrometers. Preferably, a width of the metal light-shielding layer 31 is greater than a width of the polysilicon layer 32 by 1 micrometer.

Edges of the metal light-shielding layer 31 are straight, bent, or curved. The metal light-shielding layer 31 is rectangle-shaped, or trapezoid-shaped. The shape of the metal light-shielding layer 31 is not limited thereto, as long as the metal light-shielding layer 31 could completely cover the polysilicon layer 32.

FIG. 4 shows a cross-sectional view of the array substrate of FIG. 3 along line A-A according to the present disclosure. The metal light-shielding layer 41 is insulated from the polysilicon layer 42. In addition, a width of the metal light-shielding layer 41 along the A-A direction is greater than a width of the polysilicon layer 42 along the A-A direction, such that a projection of the polysilicon layer 42 on the base plate falls within a region constricted by a projection of the metal light-shielding layer 41 on the base plate, and a thickness of the polysilicon layer 42 is uniform.

FIG. 5 shows a cross-sectional view of the array substrate of FIG. 3 along line B-B according to the present disclosure. The metal light-shielding layer 51 is insulated from the polysilicon layer 52. In addition, a width of the metal light-shielding layer 51 along the B-B direction is greater than a width of the polysilicon layer 52 along the B-B direction, such that a projection of the polysilicon layer 52 on the base plate falls within a region constricted by a projection of the metal light-shielding layer 51 on the base plate, and a thickness of the polysilicon layer 52 is uniform. Therefore, electrical property of the polysilicon layer 52 can be improved, and product yield is increased.

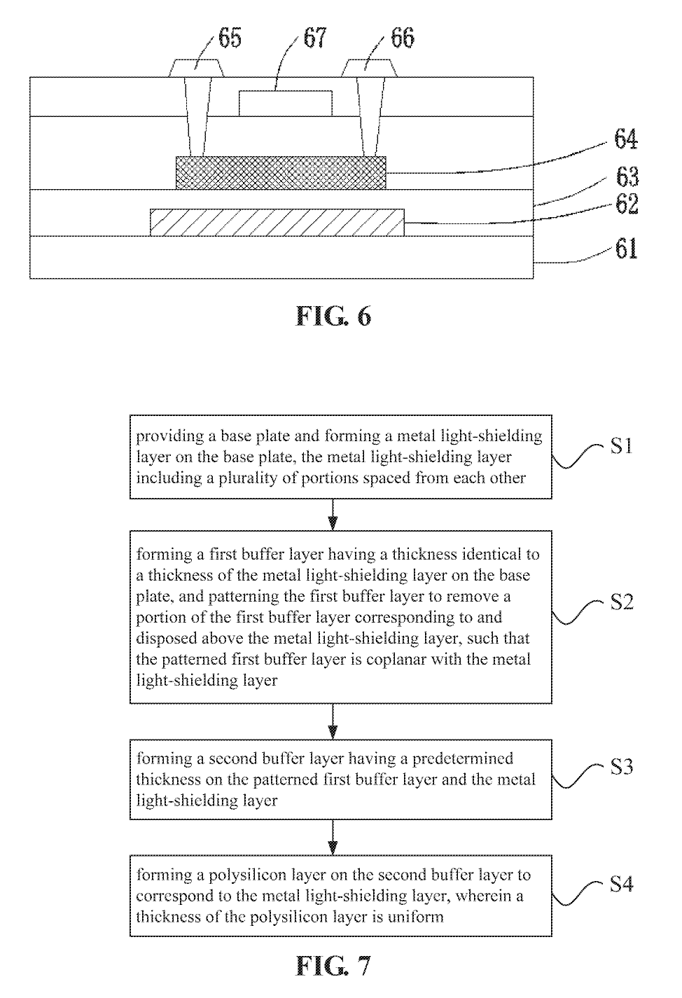

Please refer to FIG. 6, which is a schematic diagram showing a cross-sectional view of a partial structure of an array substrate according to the present disclosure. The array substrate provided by the present disclosure includes: a base plate 61; a metal light-shielding layer 62 disposed on a surface of the base plate 61, the metal light-shielding layer 62 including a plurality of portions spaced from each other; a buffer layer 63 disposed on the metal light-shielding layer 62 and the base plate 61; a polysilicon layer 64 disposed on the buffer layer 63 to correspond to the metal light-shielding layer 62; a source electrode 65 disposed at a source region of the polysilicon layer 64; a drain electrode 66 disposed at a drain region of the polysilicon layer 64; and a gate electrode 67 disposed insulatively on the polysilicon layer 64. An area of the metal light-shielding layer 62 is greater than or equal to an area of the polysilicon layer 64, and a projection of the polysilicon layer 64 on the metal light-shielding layer 62 falls within a region constricted by the metal light-shielding layer 62. Preferably, the metal light-shielding layer 62 is U-shaped, or the metal light-shielding layer 62 is rectangle-shaped, or trapezoid-shaped. A width of the metal light-shielding layer 62 is greater than a width of the polysilicon layer 64 by 0.5-2 micrometers, preferably 1 micrometer. A thickness of the polysilicon layer 64 of the array substrate in the present embodiment is uniform, therefore electrical property of the polysilicon layer 64 can be improved, and product yield is increased.

In addition, the present disclosure provides a method for manufacturing an array substrate. As shown in FIG. 7, the method includes:

a step S1 of providing a base plate and forming a metal light-shielding layer on the base plate, the metal light-shielding layer including a plurality of portions spaced from each other;

a step S2 of forming a first buffer layer having a thickness identical to a thickness of the metal light-shielding layer on the base plate, and patterning the first buffer layer to remove a portion of the first buffer layer corresponding to and disposed above the metal light-shielding layer, such that the patterned first buffer layer is coplanar with the metal light-shielding layer;

a step S3 of forming a second buffer layer having a predetermined thickness on the patterned first buffer layer and the metal light-shielding layer; and

a step S4 of forming a polysilicon layer on the second buffer layer to correspond to the metal light-shielding layer, wherein a thickness of the polysilicon layer is uniform.

Specifically, a base plate is provided first, and then a metal light-shielding layer is formed on the base plate, where the metal light-shielding layer includes a plurality of portions spaced from each other. The metal light-shielding layer is U-shaped, rectangle-shaped, or trapezoid-shaped. Edges of the metal light-shielding layer are straight, bent, or curved. Next, a buffer layer including a first buffer layer and a second buffer layer is formed on the base plate. The first buffer layer having a thickness identical to a thickness of the metal light-shielding layer is formed firstly on the base plate, and then the first buffer layer is patterned to remove a portion of the first buffer layer corresponding to and disposed above the metal light-shielding layer, such that the patterned first buffer layer is coplanar with the metal light-shielding layer. Thereafter, the second buffer layer having a predetermined thickness is formed on the patterned first buffer layer and the metal light-shielding layer. In this way, a buffer layer having a planar top surface is generated on the base plate. Finally, a polysilicon layer is formed on the second buffer layer to correspond to the metal light-shielding layer. Since the buffer layer has a planar top surface on which the polysilicon layer is formed later, a thickness of the polysilicon layer is uniform. Therefore, electrical property of the polysilicon layer can be improved. According to the present disclosure, a projection of the polysilicon layer on the base plate falls within a region constricted by a projection of the metal light-shielding layer on the base plate. Alternatively, a projection of the polysilicon layer on the base plate does not entirely overlap a projection of the metal light-shielding layer on the base plate. According to the present disclosure, the sizes and shapes of the metal light-shielding layer and the polysilicon layer formed on the array substrate are not limited to any certain sizes and shapes.

Compared to the prior art, the present disclosure is characterized in that the metal light-shielding layer is formed on the base plate to have a U-shape, a rectangle-shape, or a trapezoid-shape and to have a size larger than the polysilicon layer (just 1 micrometer wider required), so that the metal light-shielding layer completely covers the polysilicon layer. This ensures that the polysilicon layer does not cross edges of the metal light-shielding layer, avoiding the problem that the polysilicon layer at edges of metal light-shielding layer is excessively thin. Alternatively, the buffer layer is formed by formation of a first buffer layer and a second buffer layer. The first buffer layer is formed first to have a thickness identical to a thickness of the metal light-shielding layer, and then the first buffer layer is patterned such that the patterned first buffer layer is coplanar with the metal light-shielding layer. Thereafter, the second buffer layer is formed on the patterned first buffer layer and the metal light-shielding layer. Since the buffer layer has a planar top surface on which the polysilicon layer is formed later, a thickness of the polysilicon layer is uniform. Thus, electrical property of the polysilicon layer is improved, and product yield is increased.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. An array substrate, comprising:
a base plate;
a metal light-shielding layer disposed on a surface of the base plate; and
a polysilicon layer disposed on the metal light-shielding layer;
wherein an area of the metal light-shielding layer is greater than or equal to an area of the polysilicon layer, and a projection of the polysilicon layer on the metal light-shielding layer falls within a region constricted by the metal light-shielding layer; and
wherein edges of the metal light-shielding layer are straight, bent, or curved.

2. The array substrate according to claim 1, wherein the metal light-shielding layer is U-shaped.

3. The array substrate according to claim 1, wherein a width of the metal light-shielding layer is greater than a width of the polysilicon layer by 0.5-2 micrometers.

4. The array substrate according to claim 1, wherein the metal light-shielding layer is rectangle-shaped, or trapezoid-shaped.

5. A method for manufacturing an array substrate, comprising:
a step S1 of providing a base plate and forming a metal light-shielding layer on the base plate, the metal light-shielding layer including a plurality of portions spaced from each other;
a step S2 of forming a first buffer layer having a thickness identical to a thickness of the metal light-shielding layer on the base plate, and patterning the first buffer layer to remove a portion of the first buffer layer corresponding to and disposed above the metal light-shielding layer, such that the patterned first buffer layer is coplanar with the metal light-shielding layer;
a step S3 of forming a second buffer layer having a predetermined thickness on the patterned first buffer layer and the metal light-shielding layer; and
a step S4 of forming a polysilicon layer on the second buffer layer to correspond to the metal light-shielding layer, wherein a thickness of the polysilicon layer is uniform.

6. The method for manufacturing the array substrate according to claim 5, wherein the metal light-shielding layer is U-shaped, rectangle-shaped, or trapezoid-shaped.

7. The method for manufacturing the array substrate according to claim 5, wherein edges of the metal light-shielding layer are straight, bent, or curved.

8. The method for manufacturing the array substrate according to claim 5, wherein a projection of the polysilicon layer on the base plate falls within a region constricted by a projection of the metal light-shielding layer on the base plate.

9. The method for manufacturing the array substrate according to claim 5, wherein a projection of the polysilicon layer on the base plate does not entirely overlap a projection of the metal light-shielding layer on the base plate.

10. An array substrate, comprising:
a base plate;
a metal light-shielding layer disposed on a surface of the base plate; and
a polysilicon layer disposed on the metal light-shielding layer;
wherein an area of the metal light-shielding layer is greater than or equal to an area of the polysilicon layer, and a projection of the polysilicon layer on the metal light-shielding layer falls within a region constricted by the metal light-shielding layer.

11. The array substrate according to claim 10, wherein the metal light-shielding layer is U-shaped.

12. The array substrate according to claim 10, wherein a width of the metal light-shielding layer is greater than a width of the polysilicon layer by 0.5-2 micrometers.

13. The array substrate according to claim 10, wherein the metal light-shielding layer is rectangle-shaped, or trapezoid-shaped.
